(19) United States
(12) Patent Application Publication
(10) Pub. No.: US 2013/0135546 A1
(43) Pub. Date: May 30, 2013

(54) ARRAY SUBSTRATE AND LIQUID CRYSTAL PANEL

(71) Applicants: Yongcan Wang, Beijing (CN); Hongming Zhan, Beijing (CN); Lifeng Lin, Beijing (CN); Huadang Chen, Beijing (CN); BEIJING BOE OPTOELECTRONICS TECHNOLOGY CO., LTD., Beijing (CN)

(72) Inventors: Yongcan Wang, Beijing (CN); Hongming Zhan, Beijing (CN); Lifeng Lin, Beijing (CN); Huadang Chen, Beijing (CN); BEIJING BOE OPTOELECTRONICS TECHNOLOGY CO., LTD., Beijing (CN)

(73) Assignee: BEIJING BOE OPTOELECTRONICS TECHNOLOGY CO., LTD., Beijing (CN)

(21) Appl. No.: 13/698,516

(22) PCT Filed: Aug. 15, 2012
(86) PCT No.: PCT/CN2012/080165

§ 371 Date: Nov. 16, 2012

(30) Foreign Application Priority Data
Nov. 25, 2011 (CN) 201120478218.X

(51) Int. Cl. H01L 33/00; G02F 1/1343

(52) U.S. Cl. CPC H01L 33/0041; G02F 1/13439
USPC 349/33; 257/88

(57) ABSTRACT

Embodiments of the present invention disclose an array substrate and a liquid crystal panel. An embodiment of the present invention provides an array substrate comprising a plurality of pixel units, with a pixel structure of each pixel unit comprising: a first electrode and a second electrode, wherein the second electrode comprises a plurality of second electrode groups, each comprising a first common electrode group applied with a constant voltage and a second pixel electrode group applied with a first control voltage; the first electrode comprises a plurality of first electrode groups, each comprising a first pixel electrode group corresponding to the first common electrode group and applied with a second control voltage and a second common electrode group corresponding to the second pixel electrode group and applied with a constant voltage; the first pixel electrode group and the second common electrode group are composed of at least two sub-electrodes, respectively. The present invention can be applied in the field of display technology, such as a liquid crystal display.

### TECHNICAL FIELD

Embodiments of the present invention relate to an array substrate and a liquid crystal panel.

### BACKGROUND

Nowadays, liquid crystal displays have been widely used in portable mobile terminals such as mobile phones, personal digital assistants (PDAs) and the like. At present, advanced super dimension switch (ADS) mode liquid crystal panels and the like are especially used to achieve a wide viewing angle effect.

The ADS technology, by forming a multi-dimensional electric field with an electric field generated from edges of slit-electrodes in a same plane and an electric field generated between a slit-electrode layer and a plate-electrode layer, enables liquid crystal molecules in all orientations between the slit-electrodes and directly above the electrodes within a liquid crystal cell to rotate, thereby improving work efficiency of the liquid crystal and increasing light transmission efficiency. The ADS technology can improve image quality of a thin film transistor liquid crystal display (TFT-LCD) products, and has advantages of high resolution, high transmittance, low power consumption, wide viewing angle, high aperture ratio, low chromatic aberration, and no push Mura, etc.

A conventional array substrate comprises a plurality of ADS pixel structures, as shown in FIG. 1. The ADS pixel structure comprises: a common electrode 11, a pixel electrode 12 corresponding to the common electrode 11, and an insulating layer 14 provided between the common electrode 11 and the pixel electrode 12. At one end of each ADS pixel structure, there is connected a thin film transistor (TFT) 13 for controlling the pixel electrode 12. The common electrode 11 is applied with a constant voltage, while the TFT 13 varies the voltage of the pixel electrode 12, thereby varying the voltage difference between the pixel electrode 12 and the common electrode 11 and in turn varying the fringe electric field between the common electrode 11 and the pixel electrode 12. With the fringe electric field being varied, the liquid crystal molecules in the liquid crystal layer 15 located above the array substrate are enabled to rotate, thereby achieving an effect of light transmission control.

However, the inventors noted that the above-described conventional array substrate has at least the following problems: in the aforementioned ADS pixel structure, the fringe electric field generated by the common electrode and the pixel electrode is distributed non-uniformly, which causes non-uniform light transmission.

### SUMMARY

Embodiments of the present invention provide an array substrate and a liquid crystal panel, for solving the problem—in the existing pixel structure—that the fringe electric field generated by the common electrode and the pixel electrode is non-uniformly distributed, which causes non-uniform light transmission.

An embodiment of the present invention provides an array substrate, comprising a plurality of pixel units, with a pixel structure of each pixel unit comprising: a first electrode and a second electrode which overlap with each other, wherein an insulating layer is disposed between the second electrode and the first electrode, and a fringe electric field is generated by the second electrode in cooperation with the first electrode; the second electrode comprises a plurality of second electrode groups, each comprising a first common electrode group and a second pixel electrode group, with a first gap disposed between the first common electrode group and the second pixel electrode group; the first common electrode group is applied with a constant voltage, and the second pixel electrode group is applied with a first control voltage; the first electrode comprises a plurality of first electrode groups corresponding to the second electrode groups, the first electrode group comprises a first pixel electrode group and a second common electrode group, with a second gap disposed between the first pixel electrode group and the second common electrode group.

For example, the first pixel electrode group is composed of at least two sub-electrodes, the second common electrode group is composed of at least two sub-electrode, the first pixel electrode group corresponds to the first common electrode group and is applied with a second control voltage, and the second common electrode group corresponds to the second pixel electrode group and is applied with a constant voltage. By applying the second control voltage and applying the constant voltage, the voltage requirements of the whole structure are satisfied.

For example, with the pixel structure, there is disposed a first thin film transistor (TFT) for controlling the applied voltage of the first pixel electrode group. For example, with the pixel structure, there is further disposed a second TFT for controlling the applied voltage of the second pixel electrode group. By utilizing the characteristics of the TFTs to control the first pixel electrode group and the second pixel electrode group respectively, the voltage requirements of the whole structure are satisfied.

For example, the first control voltage and the second control voltage are equal in absolute values of voltage, opposite in voltage polarity and identical in frequency, and the constant voltage is 0V. In this way, the first control voltage can be obtained by inverting the second control voltage, which not only provides convenience for controlling the voltages, but at the same time, with application of a small voltage, produces a voltage difference between the first pixel electrode and the second pixel electrode group, and thereby achieving the effect of a high voltage necessary for the original pixel electrodes.

For example, the first gap and the second gap are aligned in the up-and-down direction. In this way, through the employment of the up-and-down alignment setting, the overlapping area between the second electrode and the first electrode is reduced, and accordingly the capacitance between the second electrode and the first electrode is reduced, leading to a bigger speed of varying the first control voltage and a second control voltage, and therefore the panel's response time is improved.

Another embodiment of the present invention provides a liquid crystal panel, comprising: a color filter substrate, an array substrate, and a liquid crystal layer provided between the color filter substrate and the array substrate, and the array substrate comprises a plurality of pixel structures described above.

In the array substrate and the liquid crystal panel provided by embodiments of the present invention, the pixel structure of each pixel unit comprises a first electrode and a second electrode; the second electrode comprises a plurality of second electrode groups, each comprising a first common electrode group and a second pixel electrode group, the first common electrode group is applied with a constant voltage, and the second pixel electrode group is applied with a first control voltage; the first electrode comprises a plurality of first electrode groups corresponding to the second electrode groups, and the first electrode group each comprises a first pixel electrode group and a second common electrode group. Such structure produces a horizontal electric field contained in the fringe electric field generated by the second electrode in cooperation with the first electrode, so as to make the fringe electric field distributed uniformly, thereby improving transmittance of a liquid crystal panel employing such pixel structure. This solves the problem—in the prior art—that the fringe electric field generated by the common electrode and the pixel electrode is non-uniformly distributed, which causes non-uniform light transmission.

### BRIEF DESCRIPTION OF THE DRAWINGS

In order to clearly illustrate the technical solutions of the embodiments of the invention, the drawings of the embodiments will be briefly described in the following; it is obvious that the described drawings are only related to some embodiments of the invention and thus are not limitative of the invention.

FIG. 1 is a schematic structural view of a pixel structure in the prior art;

FIG. 2 is a first schematic structural view of a pixel structure according to an embodiment of the present invention;

FIG. 3 a second schematic structural view of a pixel structure according to an embodiment of the present invention;

FIG. 4 is a schematic view of a first thin film transistor (TFT) and a second TFT in a pixel structure according to an embodiment of the present invention;

FIG. 5 is a schematic structural view of a pixel structure according to another embodiment of the present invention;

FIG. 6 are the relationship curves between the applied voltage of a pixel electrode and the transmittance, comparing the pixel structure according to another embodiment of the present invention with that of the prior art;

FIG. 7 are the relationship curves between the response time and the transmittance percentage, comparing the pixel structure according to another embodiment of the present invention with that of the prior art; and

FIG. 8 is a schematic structural view of a liquid crystal panel according to further another embodiment of the present invention.

### DETAILED DESCRIPTION

In order to make objects, technical details and advantages of the embodiments of the invention apparent, the technical solution of the embodiments will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

An embodiment of the present invention provides an array substrate for a liquid crystal display. The array substrate comprises a plurality of gate lines and a plurality of data lines, and these gate lines and data lines intersect one other and thereby define a plurality of pixel units that are arranged in a matrix. Each pixel unit comprises a thin film transistor as a switching element. The gate electrode of the thin film transistor of each pixel unit is connected to or integrally formed with the corresponding gate line, and one of the source/drain electrodes of the thin film transistor is connected to or integrally formed with the corresponding data line. Below, the description will be given for the pixel structure of each pixel unit.

The pixel structure provided by the embodiment of the present invention, as shown in FIG. 2, comprises: a first electrode 21 and a second electrode 22 which overlap with each other, with an insulating layer 23 disposed between the second electrode 22 and the first electrode 21. A fringe electric field is generated by the second electrode 22 in cooperation with the first electrode 21.

The second electrode 22 comprises a plurality of second electrode groups 221, and furthermore, the second electrode group 221 each comprises a first common electrode group 2211 and a second pixel electrode group 2212. A first gap 2213 is disposed between the first common electrode group 2211 and the second pixel electrode group 2212. The first common electrode group 2211 is applied with a constant voltage, and the second pixel electrode group 2212 is applied with a first control voltage.

The first electrode 21 comprises a plurality of first electrode groups 211 corresponding to the second electrode groups 221, and the first electrode group 211 each comprises a first pixel electrode group 2111 and a second common electrode group 2112, with a second gap 2113 disposed between the first pixel electrode group 2111 and the second common electrode group 2112.

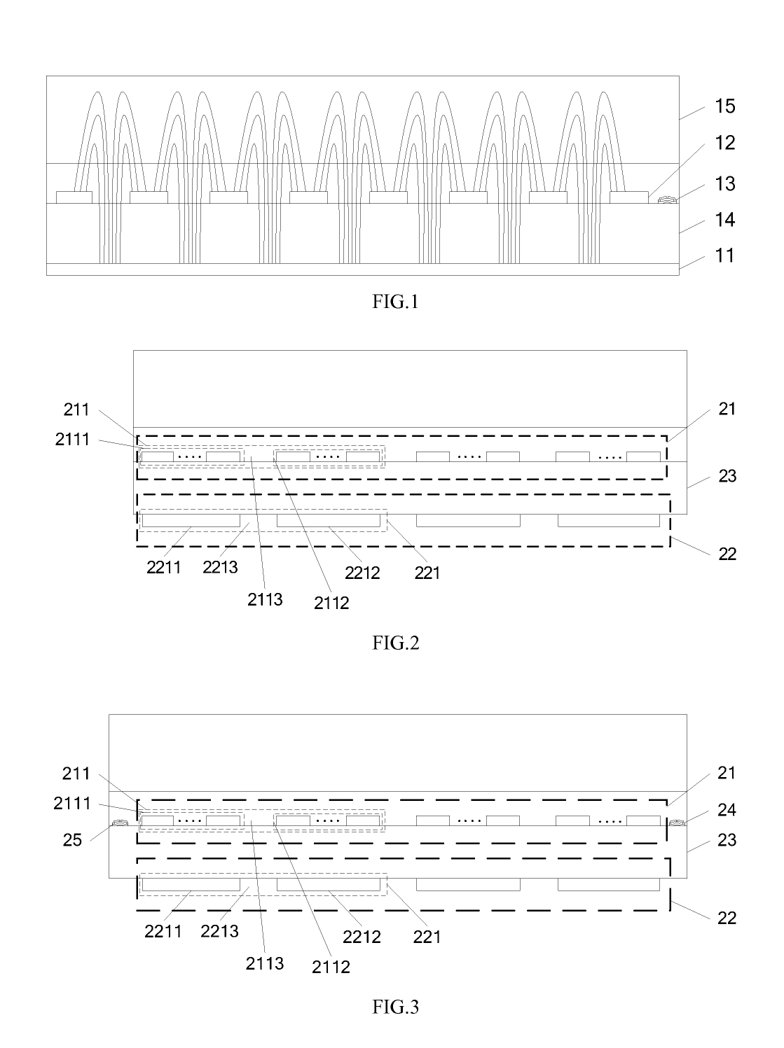

As described above, the pixel structure provided by the embodiment of the present invention comprises a second electrode and a first electrode, wherein the second electrode comprises a plurality of second electrode groups, each comprising a first common electrode group and a second pixel electrode group, the first common electrode group is applied with a constant voltage, and the second pixel electrode group is applied with a first control voltage; the first electrode comprises a plurality of first electrode groups corresponding to the second electrode groups, and the first electrode group each comprises a first pixel electrode group and a second common electrode group. Such structure can produce a horizontal electric field contained in the fringe electric field generated by the second electrode in cooperation with the first electrode, so as to make the fringe electric field distributed uniformly and accordingly improves transmittance of the liquid crystal panel employing such pixel structure. This solves the problem—in the conventional technology as shown in FIG. 1—that the fringe electric field generated by the common electrode and the pixel electrode is non-uniformly distributed, which causes non-uniform light transmission.

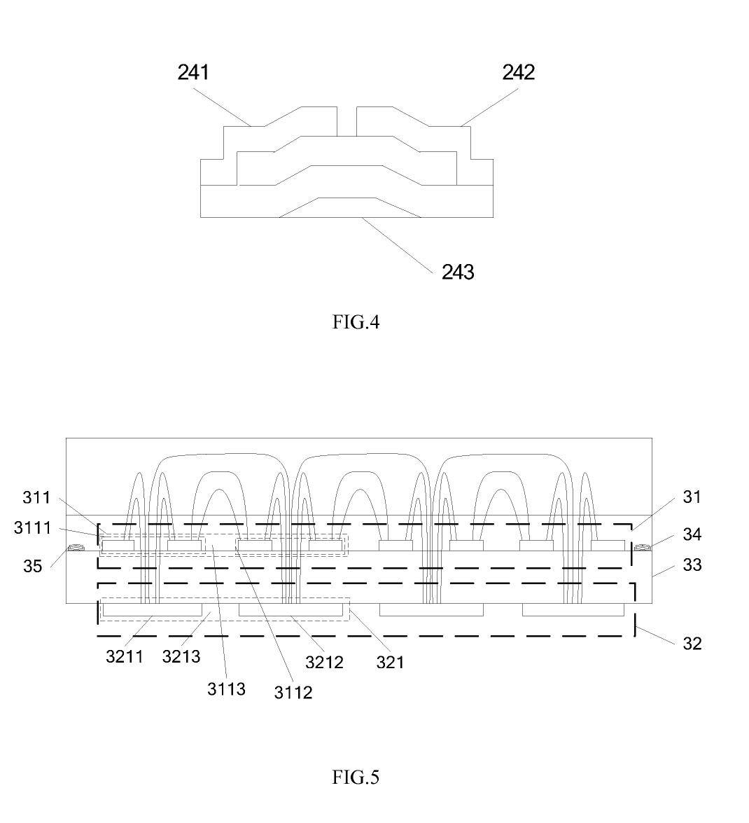

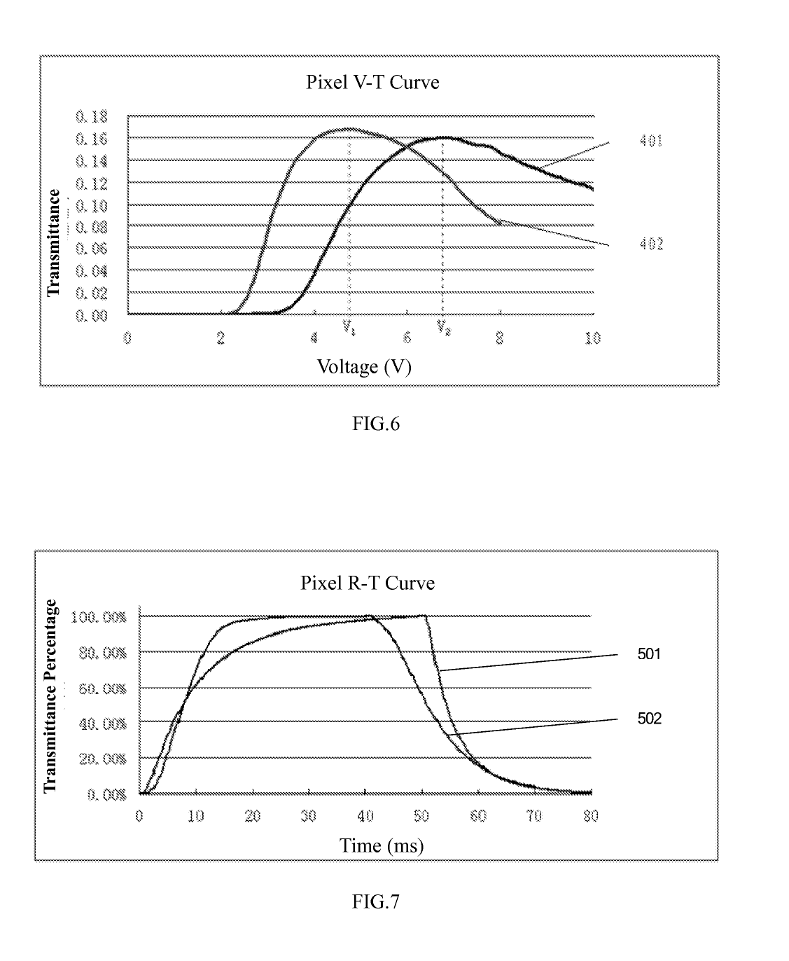

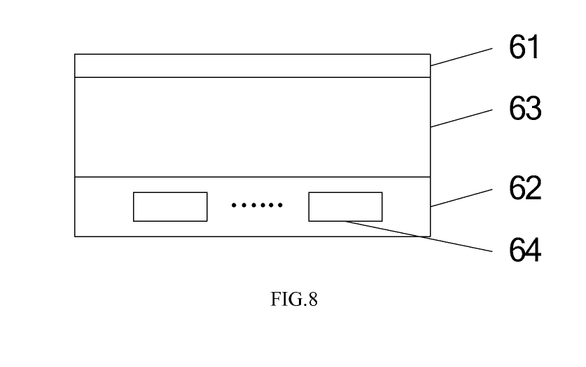

FIG. 3 illustrates another schematic view of this embodiment, further showing the control section.

Specifically, as shown in FIG. 3, the first pixel electrode group 2111 is composed of at least two sub-electrodes “a”, and the second common electrode group 2112 is composed of at least two sub-electrodes “b”. The first pixel electrode group 2111 corresponds to the first common electrode group 2211 and is applied with a second control voltage, and the second common electrode group 2112 corresponds to the second pixel electrode group 2212 and is applied with a constant voltage. By applying the second control voltage and applying the constant voltage, the voltage requirements of the whole structure are satisfied.

In one example, as shown in FIG. 3, with the pixel structure, there is disposed a first thin film transistor (TFT) 24 for controlling the applied voltage of the first pixel electrode group 2111; also with the pixel structure, there is further disposed a second TFT 25 for controlling the applied voltage of the second pixel electrode group 2212. By utilizing the characteristics of the TFTs to control the first pixel electrode group and the second pixel electrode group respectively, the voltage requirements of the whole structure are satisfied.

In one example, as shown in FIG. 4, the first thin film transistor (TFT) 24 and the second TFT 25 may be identical to each other in structure, each comprising: a TFT source electrode 241, a TFT drain electrode 242, a TFT gate electrode 243, a gate insulating layer 244, and an active layer 245.

For example, the first control voltage and the second control voltage may be equal in absolute value of voltage, opposite in voltage polarity, and identical in frequency; the constant voltage is, for example, 0V. In this way, the first control voltage can be obtained by inverting the second control voltage; furthermore, it not only provides convenience for controlling the voltages, but at the same time, with application of a small voltage, produces a voltage difference between the first pixel electrode and the second pixel electrode group, thereby achieving the effect of a high voltage necessary for the original pixel electrodes.

For example, if the second control voltage is a voltage of +1V, then a voltage of −1V can be obtained only by an inverting process for the voltage value of the second control voltage, and then applied to the second pixel electrode group, forming a first control voltage.

For example, the first gap 2213 and the second gap 2113 are aligned in up-and-down direction. In this way, through the employment of the up-and-down alignment, the overlapping area between the second electrode and the first electrode is reduced, and accordingly the capacitance between the second electrode and the first electrode is reduced, leading to a bigger speed of varying the first control voltage and the second control voltage, and therefore the panel's response time is improved.

In order to make the technical solution provided by the embodiments of the present invention better understood for the skilled in the art, a pixel structure according to another embodiment of the invention will be described in detail now.

The pixel structure according to another embodiment of the invention, as shown in FIG. 5, comprises a first electrode 31 and a second electrode 32 which overlap with each other, with an insulating layer 33 provided between the second electrode 32 and the first electrode 31, and a fringe electric field is generated by the second electrode 32 in cooperation with the first electrode 31. The curves in FIG. 5 represent the electric fluxlines in the electric field that are generated as a result of the voltage difference applied between the first electrode 31 and the second electrode 32.

The second electrode 32 comprises a plurality of second electrode groups 321, and the second electrode group 321 each comprises a first common electrode group 3211 and a second pixel electrode 3212, with a first gap 3213 provided between the first common electrode group 3211 and the second pixel electrode group 3212. The first common electrode group 3211 is applied with a constant voltage, and the second pixel electrode group 3212 is applied with a first control voltage.

The first electrode 31 comprises a plurality of first electrode groups 311 corresponding to the second electrode groups 321, and the first electrode group 311 each comprises a first pixel electrode group 3111 and a second common electrode group 3112, with a second gap 3113 provided between the first pixel electrode group 3111 and the second common electrode group 3112. The first pixel electrode group 3111 is composed of two sub-electrodes “a”, and the second common electrode group 3112 is composed of two sub-electrodes “b”. The first pixel electrode group 3111 corresponds to the first common electrode group 3211 and is applied with a second control voltage, and the second common electrode group 3112 corresponds to the second pixel electrode group 3212 and is applied with a constant voltage.

In this embodiment, with the pixel structure, there is disposed a first thin film transistor (TFT) 34 for controlling the applied voltage of the first pixel electrode group 3111; also with the pixel structure, there is further disposed a second TFT 35 for controlling the applied voltage of the second pixel electrode group 3212. By utilizing the characteristics of the TFTs to control the first pixel electrode group and the second pixel electrode group respectively, the voltage requirements of the whole structure are satisfied.

In one example, the first control voltage and the second control voltage are, for example, equal in absolute values of voltage, opposite in voltage polarity and identical in frequency; the constant voltage is, for example, 0V. In this way, the first control voltage can be obtained by inverting the second control voltage, which not only provides convenience for controlling the voltages, but at the same time, with application of a small voltage, produces a voltage difference between the first pixel electrode and the second pixel electrode group, thereby achieving the effect of a high voltage necessary for the original pixel electrodes.

In this embodiment, simulation experiments are conducted for the above-described pixel structure. As shown in FIG. 6, the voltage-transmittance relationship curve 402 of this embodiment is obtained. Compared with the voltage-transmittance relationship curve 401 of the prior art, the pixel structure provided in this embodiment can achieve a transmittance of 0.168, while the transmittance is 0.159 in the prior art; therefore, it can be seen that the transmittance of the modified pixel is improved. Moreover, in the case for reaching the maximum transmittance, the applied voltage of the first electrode in this embodiment V1=4.8V, is lower than the applied voltage of the pixel electrode in the prior art V2=6.8V. Further, the first gap 3213 and the second gap 3113 are aligned in the up-and-down direction. In this way, through the employment of the up-and-down alignment setting, the overlapping area between the second electrode and the first electrode is reduced, and accordingly the capacitance between the second electrode and the first electrode is reduced, leading to a bigger speed of varying the first control voltage and a second control voltage, and therefore the panel's response time is improved.

In this embodiment, simulation experiments are conducted for the above-described pixel structure, as shown in FIG. 7, and the response time-transmittance percentage relationship curve 502 of this embodiment is obtained. Compared with the response time-transmittance percentage relationship curve 501 of the prior art, the black-and-white response time curves, respectively obtained from RT response time simulations conducted at the voltages corresponding to the maximum transmittances, are as follows: curve 501, Tᵣ=22.3 ms, T_{f}=11.8 ms, T=Tᵣ+T_{f}=34.1 ms; and curve 502, T′ᵣ=9.9 ms, T′_{f}=19.1 ms, T′=T′ᵣ+T′_{f}=29 ms. Since T′<T, it can be seen that the response speed in this embodiment is superior to that in the prior art. Tᵣ is the response time required for the transmittance percentage to change from 10% to 90% in the prior art; T_{f} is the response time required for the transmittance percentage to change from 90% to 10% in the prior art; T′ᵣ is the response time required for the transmittance percentage to change from 10% to 90% in this embodiment; and T′_{f} is the response time required for the transmittance percentage to change from 90% to 10% in this embodiment.

This embodiment of the invention provides a pixel structure, the pixel structure comprising a second electrode and a first electrode, wherein the second electrode comprises a plurality of second electrode groups, each comprising a first common electrode group and a second pixel electrode group, the first common electrode group is applied with a constant voltage, and the second pixel electrode group is applied with a first control voltage; the first electrode comprises a plurality of first electrode groups corresponding to the second electrode groups, the first electrode group each comprise a first pixel electrode group and a second common electrode group, the first pixel electrode group corresponds to the first common electrode group and is applied with a second control voltage, and the second common electrode group corresponds to the second pixel electrode group and is applied with a constant voltage; moreover, both the first pixel electrode group and the second common electrode group are composed of two sub-electrodes. Such structure produces a horizontal electric field contained in the fringe electric field generated by the second electrode in cooperation with the first electrode, so as to make the fringe electric field distributed uniformly, thereby improving transmittance of a liquid crystal panel employing such pixel structure. This solves the problem—in the prior art—that the fringe electric field generated by the common electrode and the pixel electrode is non-uniformly distributed, which causes non-uniform light transmission.

Further another embodiment of the present invention provides a liquid crystal panel, as shown in FIG. 8, comprising: a color filter substrate 61, an array substrate 62, and a liquid crystal layer 63 disposed between the color filter substrate and the array substrate; the array substrate 62 comprises a plurality of pixel structures 64 described above. The pixel structure 64 each is, for example, the same as that in the embodiment shown in FIG. 2, for which the description is omitted here.

This embodiment of the invention provides a liquid crystal panel, and the pixel structure on the array substrate thereof comprises: a second electrode and a first electrode; the second electrode comprises a plurality of second electrode groups, each comprising a first common electrode group and a second pixel electrode group, the first common electrode group is applied with a constant voltage, and the second pixel electrode group is applied with a first control voltage; the first electrode comprises a plurality of first electrode groups corresponding to the second electrode groups, and the first electrode group each comprises a first pixel electrode group and a second common electrode group. Such structure produces a horizontal electric field contained in the fringe electric field generated by the second electrode in cooperation with the first electrode, so as to make the fringe electric field distributed uniformly, thereby improving transmittance of a liquid crystal panel employing such pixel structure. This solves the problem—in the prior art—that the fringe electric field generated by the common electrode and the pixel electrode is non-uniformly distributed, which causes non-uniform light transmission.

The protection scope of the invention should be defined by the protection scope of the claims.

1. An array substrate comprising a plurality of pixel units, with a pixel structure of each pixel unit comprising:
a first electrode and a second electrode which overlap with each other,
wherein an insulating layer is disposed between the second electrode and the first electrode, and a fringe electric field is generated by the second electrode in cooperation with the first electrode,
wherein the second electrode comprises a plurality of second electrode groups, each comprising a first common electrode group and a second pixel electrode group, with a first gap disposed between the first common electrode group and the second pixel electrode group, wherein the first common electrode group is applied with a constant voltage, and the second pixel electrode group is applied with a first control voltage; and
the first electrode comprises a plurality of first electrode groups corresponding to the second electrode groups, and the first electrode group each comprises a first pixel electrode group and a second common electrode group, with a second gap disposed between the first pixel electrode group and the second common electrode group.

2. The array substrate according to claim 1, wherein the first pixel electrode group is composed of at least two sub-electrodes, and the second common electrode group is composed of at least two sub-electrode, the first pixel electrode group corresponds to the first common electrode group and is applied with a second control voltage, and the second common electrode group corresponds to the second pixel electrode group and is applied with a constant voltage.

3. The array substrate according to claim 1, wherein with the pixel structure, there is disposed a first thin film transistor (TFT) for controlling the applied voltage of the first pixel electrode group.

4. The array substrate according to claim 1, wherein with the pixel structure, there is further disposed a second TFT for controlling the applied voltage of the second pixel electrode group.

5. The array substrate according to claim 1, wherein the first control voltage and the second control voltage are equal in absolute values of voltage, opposite in voltage polarity and identical in frequency, and the constant voltage is 0V.

6. The array substrate according to claim 1, wherein the first gap and the second gap are aligned in an up-and-down direction.

7. A liquid crystal panel, comprising a color filter substrate, an array substrate, and a liquid crystal layer provided between the color filter substrate and the array substrate, wherein the array substrate is according to claim 1.

8. The array substrate according to claim 3, wherein with the pixel structure, there is further disposed a second TFT for controlling the applied voltage of the second pixel electrode group.
